(19) United States
(12) Patent Application Publication
(10) Pub. No.: US 2013/0249228 A1
(43) Pub. Date: Sep. 26, 2013

(54) VACUUM NOZZLE DEVICE FOR SUCKING AND MOVING AN OPTOELECTRICAL ELEMENT

(71) Applicant: CHIH-CHEN LAI, Tu-Cheng (TW)

(72) Inventor: CHIH-CHEN LAI, Tu-Cheng (TW)

(73) Assignee: HON HAI PRECISION INDUSTRY CO., LTD., Tu-Cheng (TW)

(21) Appl. No.: 13/541,663

(22) Filed: Jul. 4, 2012

(30) Foreign Application Priority Data
Mar. 23, 2012 (TW) 101110014

(51) Int. Cl. H01L 21/683; B25J 15/06

(52) U.S. Cl. 294/185

(57) ABSTRACT

A vacuum nozzle device for picking up and moving a light emitting diode comprises a tube having a lower end for contacting the light emitting diode and an image sensor located in the vacuum nozzle device. A negative pressure can be generated at the lower end of the tube when the vacuum nozzle device is in operation. The image sensor detects alignment keys on a light generating chip of the LED to precisely move the vacuum nozzle device to a desired position on the light emitting diode.

### BACKGROUND

1. Technical Field

The disclosure generally relates to a vacuum nozzle device for sucking and positioning an optoelectrical element, and particularly to a vacuum nozzle for precisely sucking and positioning a light emitting diode (LED), whereby the light emitting diode can be precisely mounted on a target object, which is, for example, a printed circuit board.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

In assembly, an LED is picked up by a nozzle and placed at a predetermined position of a substrate, which is, for example, a printed circuit board (PCB) or a metal cored printed circuit board (MCPCB). Generally, an image sensor, for example, a charge-coupled device (CCD) is provided below the LED to identify the position of the LED, thereby avoiding the LED being deviated from the predetermined position to be picked up by the nozzle. The image sensor detects the geometric shape of the LED to decide the center of the LED. The nozzle picks up the LED by sucking the geometric center of the LED. A deviation of 50 μm can happen between the sucked position of the nozzle and the geometric center of the LED by such technology. For an optoelectrical element like an LED, the positional deviation of 50 μm is not good enough for the more and more demanding requirement of precise positioning of the LED. Furthermore, the chip of the LED from which light of the LED comes may not be at the geographic center of the LED due to the packaging tolerance. When this happens, even the nozzle picks up the LED by sucking the geographic center of the LED, the light from the LED chip is still deviated from its intended position. Finally, the relative position between the nozzle and the image sensor needs to be frequently calibrated thereby making sure that the nozzle can be moved to the correct position. The calibration is time consuming, thereby being costly.

What is needed, therefore, is a vacuum nozzle device to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross-sectional view showing a light emitting diode.

FIG. 2 is a cross-sectional view showing a vacuum nozzle device in accordance with the present disclosure which is positioned on the light emitting diode of FIG. 1.

FIG. 3 is a top view of the vacuum nozzle device of FIG.2.

### DETAILED DESCRIPTION

An embodiment of a vacuum nozzle device for precisely positioning a light emitting diode will now be described in detail below and with reference to the drawings.

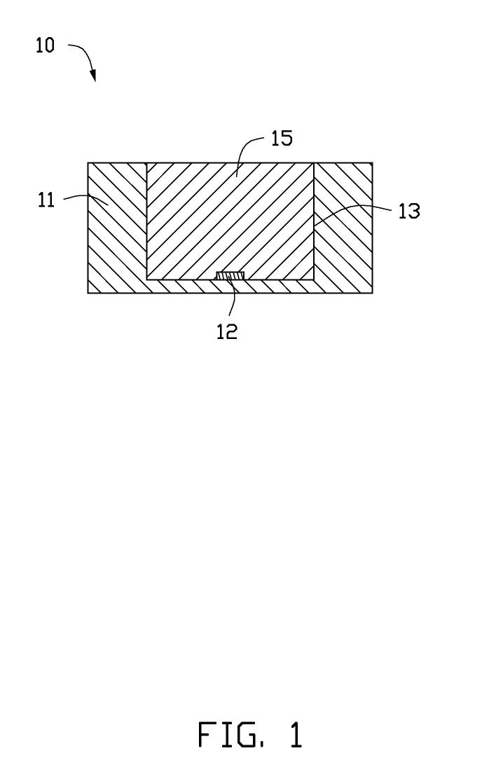

Referring to FIG. 1, an optoelectrical element, such as a light emitting diode 10 is provided. The light emitting diode 10 includes a U-shaped substrate 11 and an LED chip 12 received in the substrate 11 and on a top of a bottom wall of the substrate 11. The LED chip 12 is for generating light for the light emitting diode 10. In this embodiment, a cylindrical recess 13 is defined at a central portion of the substrate 11, and the LED chip 12 is arranged at a bottom of the recess 13. Two alignment keys (not shown) are formed on an upper surface of the LED chip 12. The alignment keys usually are cross marks on the upper surface of the LED chip 12, which are well known to person skilled in the art and use for positioning the LED chip 12 at the required position when packaging the LED chip 12 in the light emitting diode 10. Preferably, the recess 13 further includes a transparent encapsulation 15 to cover the LED chip 12. The transparent encapsulation 15 can also be doped with phosphors to convert light from the LED chip 12 into light with a different wavelength.

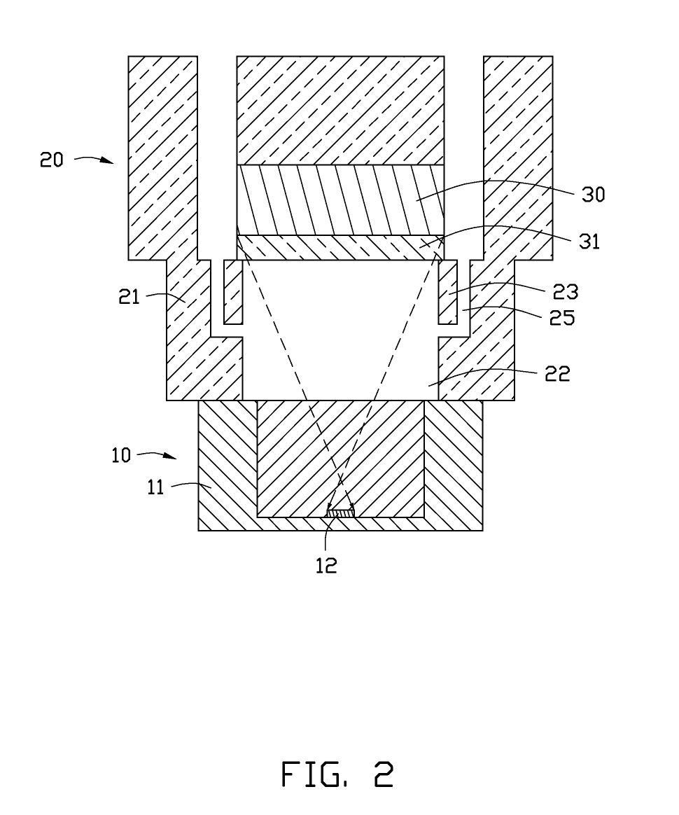

Referring also to FIG. 2, a vacuum nozzle device 20 in accordance with the present disclosure is provided. The vacuum nozzle device 20 includes a tube 21. The tube 21 defines an opening 22 in a bottom thereof to pick up the light emitting diode 10.

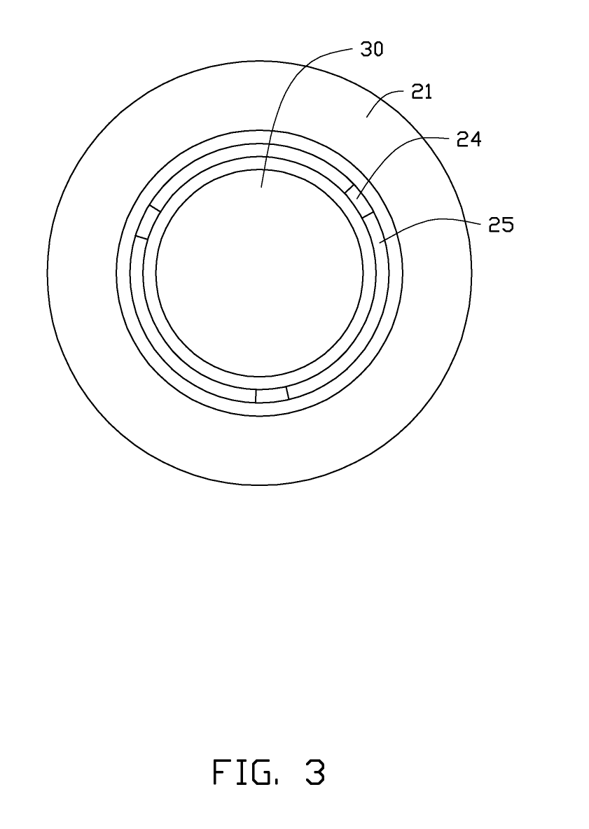

When the opening 22 of the tube 21 is closed by a top face of the light emitting diode 10, the tube 21 is vacuumed to generate a negative pressure at the opening 22, thereby making the light emitting diode 10 being sucked by the tube 21. Referring also to FIG. 3, the vacuum nozzle device 20 further includes a fixing ring 23 located inside the tube 21. The fixing ring 23 is secured to the tube 21 by supporting poles 24. A passage 25 is defined between every two adjacent supporting poles 24 for exhaustion of air from the tube 21 when the vacuum nozzle device 20 is operated to pick up the light emitting diode 10.

The vacuum nozzle device 20 further includes an image sensor 30 positioned inside the tube 21. The image sensor 30 determines a position of the LED chip 12 by detecting the alignment keys on the upper surface of the LED chip 12. In this embodiment, the image sensor 30 is a charge-coupled device (CCD), which is secured on the fixing ring 23. A transparent glass layer 31 is formed between the image sensor 30 and the fixing ring 23 to prevent the image sensor 30 from being contaminated by dust or other particles when the vacuum nozzle device 20 is in operation.

In operation to pick up the light emitting diode 10, the image sensor 30 positioned inside the vacuum nozzle device 20 detects the position of the LED chip 12 by sensing the positions of the alignment keys, rather than a geometry shape of the light emitting diode 10. By such technology, a possible deviation between the actually sucked position of the vacuum nozzle device 20 and its intended position is within 10 μm, whereby the light emitting diode 10 can be more precisely positioned by the vacuum nozzle device 20. Furthermore, even though the LED chip 12 is deviated from a predetermined position inside the light emitting diode 10, since the vacuum nozzle device 20 picks up the LED 10 by detecting the alignment keys on the LED chip 12 rather the geometry shape of the LED 10, the tube 21 is aligned with the LED chip 12 during the pick-up operation. Accordingly, the LED chip 12 can be located at its intended position after it is moved by the vacuum nozzle device 20 to be positioned on a target object, for example, a printed circuit board or a metal cored printed circuit board. Thus, light generated by the LED chip 12 will not be unduly deviated from its intended position.

The tube 21 of the vacuum nozzle device 20 can be made of a transparent material selected from a group consisting of glass, polycarbonate (PC), and polymethyl methacrylate (PMMA). Light from outer environment can pass through the transparent tube 21 and illuminate the LED chip 21 inside the light emitting diode 10. Therefore, the image sensor 30 can determine the position of the LED chip 21 more efficiently and correctly. In addition, a light source can be positioned inside the tube 21 to illuminate the light emitting diode 10 to facilitate the image sensor 30 to sense the position of the LED chip 12.

The use of the vacuum nozzle device 20 is illustrated hereafter. First, the vacuum nozzle device 20 is moved to a place generally above the light emitting diode 10. The image sensor 30 is then operated to detect the position of the alignment keys of the LED chip 12 whereby the vacuum nozzle device 20 is further moved to its intended position over the light emitting diode 20 at which the tube 21 of the vacuum nozzle device 20 is aligned with the LED chip 12. The vacuum nozzle device 20 is lowered to have the tube 21 in contact with a top surface of the LED 10. The vacuum nozzle device 20 is then operated to generate a vacuum pressure on the light emitting diode 10 whereby the light emitting diode 10 can be picked up by the vacuum nozzle device 20 and moved thereby to a desired position.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

1. A nozzle for picking up an element, comprising:
a tube, defining an opening in a bottom end thereof, the tube being configured to be vacuumed to generate a negative pressure at the opening for picking up the element; and
an image sensor located inside the tube for determining a position of the element.

2. The nozzle of claim 1, wherein the image sensor is a charge-coupled device.

3. The nozzle of claim 1, wherein a fixing ring is secured inside the tube, the fixing ring is connected with the tube by supporting poles, and a passage is defined between every two adjacent supporting poles for air to pass through in the vacuuming process.

4. The nozzle of claim 3, wherein the image sensor is positioned on the fixing ring.

5. The nozzle of claim 4, wherein a transparent glass layer is formed between the image sensor and the fixing ring.

6. The nozzle of claim 1, wherein the tube of the nozzle is made of a transparent material.

7. The nozzle of claim 6, wherein a material of the tube is selected from a group consisting of glass, polycarbonate, and polymethyl methacrylate.

8. The nozzle of claim 1, wherein the element is an optoelectrical element.

9. The nozzle of claim 8, wherein the element is a light emitting diode.

10. The nozzle of claim 9, wherein the light emitting diode comprises a substrate and a light generating chip mounted on the substrate and the image sensor is for determining a position of the light generating chip.

11. A use of a nozzle for positioning a light emitting diode which has a light generating chip having at least an alignment key thereon, the nozzle having an image sensor therein, comprising:
having the image sensor detecting the position of the at least an alignment key to move the nozzle to a desired position over the light emitting diode;
lowering the nozzle to have the nozzle in contact with the light emitting diode;
driving the nozzle to generate a vacuum whereby the light emitting diode is sucked and picked up by the nozzle.

12. The use of a nozzle of claim 11, wherein the image sensor is a charge-coupled device.

13. The use of a nozzle of claim 11, wherein the light emitting diode has an encapsulant covering the light emitting chip.

14. The use of a nozzle of claim 13, wherein the encapsulant is doped with wavelength converting particles.

15. The use of a nozzle of claim 11, wherein the nozzle has a tube in contact with the light emitting diode, the tube being made of transparent material.

16. A method for positioning a lighting element, comprising following steps:
providing a lighting element, the lighting element comprising a substrate and an LED chip formed on the substrate, the LED chip comprising an alignment key on a top surface thereof;
providing a nozzle, comprising a tube and an image sensor located inside the tube, the tube defining an opening in a bottom end thereof;
positioning the tube on the substrate with the opening aligning with the lighting element, and vacuuming the tube to generate a negative pressure at the opening, thereby connecting the tube with the lighting element, wherein during the positioning of the tube on the substrate, the image sensor located inside the tube determines a position of the LED chip by detecting the alignment key on the LED chip.

17. The method of claim 16, wherein the image sensor is a charge-coupled device.

18. The method of claim 16, wherein a cylindrical recess is defined at a central portion of the substrate, and the LED chip is arranged at a bottom of the recess.

19. The method of claim 18, wherein the recess is filled with transparent materials.

20. The method of claim 16, wherein a fixing ring is secured inside the tube, the fixing ring is connected with the tube by supporting poles, and a passage is defined between every two adjacent supporting poles for air to pass through in the vacuuming process.
